(19) United States
(12) Patent Application Publication
(10) Pub. No.: US 2007/0285902 A1
(43) Pub. Date: Dec. 13, 2007

(54) Low profile flash drive memory storage device

(75) Inventor: Daniel G. Beneke, Woodbury, MN (US)

Correspondence Address: Attention: Eric D. Levinson;Imation Corp., Legal Affairs, P.O. Box 64898, St. Paul, MN, 55164-0898, US

(73) Assignee: Imation Corp.

(21) Appl. No.: 11/449,541

(22) Filed: Jun. 7, 2006

(51) Int. Cl. H05K 1/14

(52) U.S. Cl. 361/737; 439/76.1

(57) ABSTRACT

A USB flash drive memory storage device includes a printed circuit board, a case, and a connector rigidly coupled to the case. In particular, the case defines a base end and a trailing end opposite the base end, and the connector extends a connector length from the base end of the case. The connector defines an opening through which data pads of the printed circuit assembly are accessible. The case and the connector combine to enclose the printed circuit board. In this regard, the case defines a case length extending between the base end and the trailing end that is not greater than the connector length.

### THE FIELD OF THE INVENTION

Aspects of the present invention relate to flash memory storage devices, and more particularly, to low profile USB flash drive memory storage devices useful in extending operating system memory of a computer.

### BACKGROUND

Flash memory storage devices have gained wide acceptance from users of electronic devices. Flash memory storage devices are highly portable, durable, and the memory storage is electronic, so there are no moving parts of the memory device that could potentially fail and cause a loss of data.

Flash memory is a solid-state, non-volatile, rewritable memory that has attributes of random access memory (RAM) and hard disk drive memory. Flash memory is a permanent memory that stores bits of data electronically in memory cells, similar to dynamic random access memory (DRAM), but it also has attributes of a hard disk drive in that when the power is turned off, the data remains in memory. Because of its high speed, durability, and low voltage requirements, flash memory is ideal for use in many applications, such as computers, including laptop computers, digital cameras, cell phones, printers, handheld computers, pagers, and audio recorders.

One useful flash memory storage device is a USB flash drive that is insertable into a memory port/bus of an electronic device. USB flash drives include a universal serial bus (USB) that has a standardized size and pin configuration that can be inserted into standardized USB ports in electronic devices. The USB Standards were developed by a group of companies that belong to the USB Implementers Forum, Inc. The USB Standards promote the advancement and adoption of universal serial bus technologies. To this end, USB flash drives are portable, permanent memory storage devices that provide a non-volatile form of data storage.

Portable electronic devices have become widely available. These portable devices, which include laptop computers, can be carried by a user and accessed in a variety of environments. For example, laptop computer users commonly carry and use their laptops on public transportation such as on buses, in libraries and coffee shops, and across nearly all college campuses. With this in mind, data collected and stored in one environment, for example, data stored on a hard drive of a shared system of a college campus, can be saved to a flash drive and carried by the user to a second, separate environment for use in their personal computers.

Using flash drives in portable electronic devices can present some challenges. For example, although memory storage on a flash drive is permanent and non-volatile, twisting or bending of the flash drive after it is inserted into a computer is likely to damage some portion of the computer and/or some portion of the flash drive. Thus, the risk of damaging or disconnecting the flash drive from a portable electronic device can limit a user's desire to port/carry the device, which decreases the overall usefulness of the portable electronic device.

Flash drives, and USB flash drives in particular, have proven to be a popular and convenient form of permanently storing data in a portable format. Improvements in the portability and usability of USB flash drives will be welcomed by users of portable electronics. For this and other reasons, there is a need for the present invention.

### SUMMARY

Some embodiments in accordance with principles of the present application relate to a USB flash drive memory storage device that includes a printed circuit board, a case, and a connector rigidly coupled to the case. In particular, the case defines a base end and a trailing end opposite the base end, and the connector extends a connector length from the base end of the case. The connector defines an opening through which data pads of the printed circuit assembly are accessible. The case and the connector combine to enclose the printed circuit board. In this regard, the case defines a case length extending between the base end and the trailing end that is not greater than the connector length.

Other embodiments relate to computing systems that include a housing defining an enclosure, a central processing unit disposed within the enclosure, and a USB flash drive coupleable with the housing. The housing includes a memory port, and includes a footprint having a longitudinal dimension extending between opposing sides of the housing and a lateral dimension extending between opposing ends of the housing. The USB flash drive includes a printed circuit board, a case defining a case length extending between a base end and a trailing end opposite the access end, and a connector rigidly coupled to the base end of the case. The connector is removably coupleable to the central processing unit via the memory port, and the case and the connector combining to rigidly enclose the printed circuit board. In this regard, when the USB flash drive is inserted into the memory port, the case length extends from the housing by less than 10% of the longitudinal dimension and less than 10% of the lateral dimension of the footprint.

Yet other embodiments relate to a method of accessing memory or a portable electronic device. The method includes providing a portable computer having a system memory and providing an external memory device. The external memory device includes a printed circuit assembly, a case defining a case length extending between a base end and a trailing end opposite the base end, and a connector rigidly coupled to and extending a connector length from the base end of the case. The case and the connector combine to rigidly enclose the printed circuit assembly. The method additionally includes plugging a leading end of the connector of the external memory device into a USB port of the computer, where the external memory device provides an accessible extension of the system memory. In this regard, the case and the connector combine to define an enclosure having a device length extending between the leading end of the connector and the trailing end of the case, and the case length is less than 50% of the device length.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 illustrates a perspective view of a computing system including a USB flash drive extended system memory device according to one embodiment of the present invention;

FIG. 2 illustrates a top view of the computing system illustrated in FIG. 1;

FIG. 3A illustrates an exploded, perspective view of a USB flash drive according to one embodiment of the present invention;

FIG. 3B illustrates an exploded side view of the USB flash drive illustrated in FIG. 3A;

FIG. 3C illustrates a side view of the USB flash drive illustrated in FIG. 3B when assembled;

FIG. 4A illustrates an exploded, perspective view of another USB flash drive according to one embodiment of the present invention;

FIG. 4B illustrates an exploded side view of the USB flash drive illustrated in FIG. 4A;

FIG. 4C illustrates a side view of the USB flash drive illustrated in FIG. 4B when assembled;

FIG. 5A illustrates a perspective view of another USB flash drive according to one embodiment of the present invention;

FIG. 5B illustrates a top view of the USB flash drive illustrated in FIG. 5A;

FIG. 6A illustrates a perspective view of another USB flash drive according to one embodiment of the present invention;

FIG. 6B illustrates a top view of the USB flash drive illustrated in FIG. 6A;

FIG. 7A illustrates a perspective view of another USB flash drive according to one embodiment of the present invention; and

FIG. 7B illustrates a top view of the USB flash drive illustrated in FIG. 7A.

### DETAILED DESCRIPTION

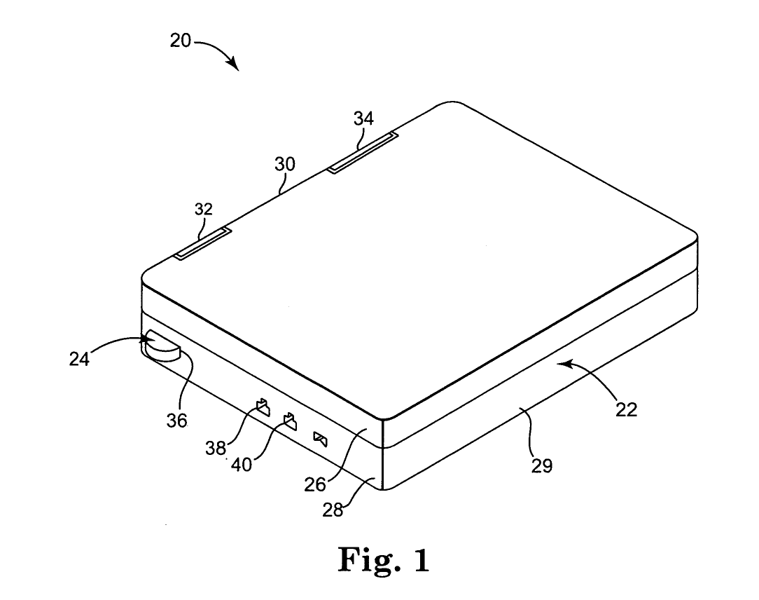

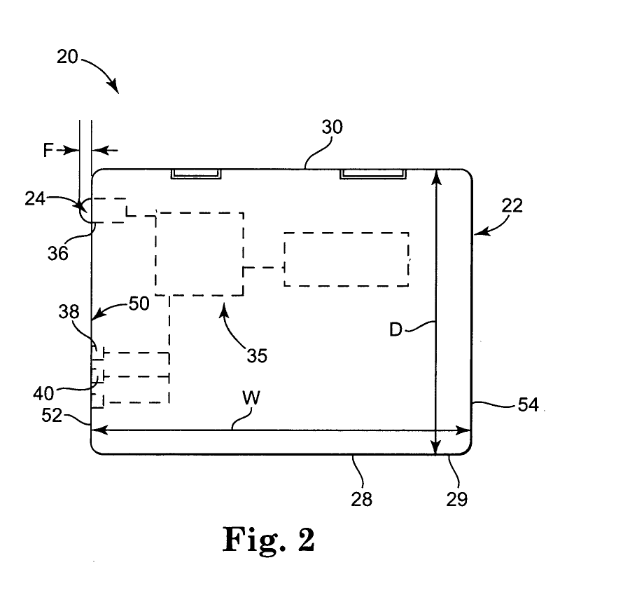

FIGS. 1 and 2 illustrate a perspective view of a computing system 20 and a top view of a portion of the computing system 20, respectively, according to embodiments of the present invention. The computing system 20 includes a portable electronic device in the form of a computer 22, and a USB flash drive 24 memory storage device that is insertable into the computer 22 to extend operating system memory of the computer 22.

The computer 22 is akin to a conventional laptop computer and includes a monitor portion 26 and a housing 28. In one embodiment, the monitor portion 26 is hinged to the housing 28 along a hinged back side 30. For example, the hinged back side 30 includes a first hinge 32 and a second hinge 34, where the hinges 32, 34 are coupled between the monitor portion 26 and the housing 28 to permit the monitor portion 26 to be opened relative to the housing 28. With this in mind, the computer 22 is a portable laptop-style of computer, although other portable electronic devices, including handheld devices, are also acceptable and within the scope of this application.

In general, the housing 28 forms an enclosure around a central processing unit (“CPU”) 35 and includes multiple ports that are electrically connected to the CPU 35. For example, a memory port 36 is formed in the housing 28 and configured to receive a portion of the USB flash drive 24. In one embodiment, the memory port 36 is a universal serial bus (USB) port configured to receive a connector portion of the USB flash drive 24. Peripheral ports 38, 40 are also formed in the housing 28 and are suited for electrically connecting peripheral devices (not shown) to the computer 22.

FIG. 2 illustrates a top view of a portion of the computing system 20. As a point of reference, the monitor portion 26 (FIG. 1) is not illustrated, and other portions such as a keyboard and power unit(s) are not shown for ease of illustration. With this in mind, the housing 28 defines an enclosure 50 housing the CPU 35. The housing 28 is bounded by opposing sides 29, 30 and opposing ends 52, 54. In this regard, an external perimeter of the housing 28 defines a footprint having a longitudinal dimension D extending between the opposing sides 29, 30, and a lateral dimension W extending between the opposing ends 52, 54 of the housing 28.

The USB flash drive 24 is portable and removably insertable into the housing 28. Inserting the portable USB flash drive 24 into the housing 28 will result in a portion of the USB flash drive 24 extending beyond the footprint of the housing 28. Specifically, in one embodiment the USB flash drive 24 includes a USB connector configured and sized to be inserted and connected within a conventional USB connector port. Inserting and fully engaging the USB connector into the memory port 36 results in only a case length F of the USB flash drive 24 projecting from the housing 28. In this manner, the USB flash drive 24 minimizes a disruption of the footprint of the housing 28 where the case length F extends away from the housing 28 by less than 10 percent of the longitudinal dimension D and less than 10 percent of the lateral dimension W of the housing 28 footprint.

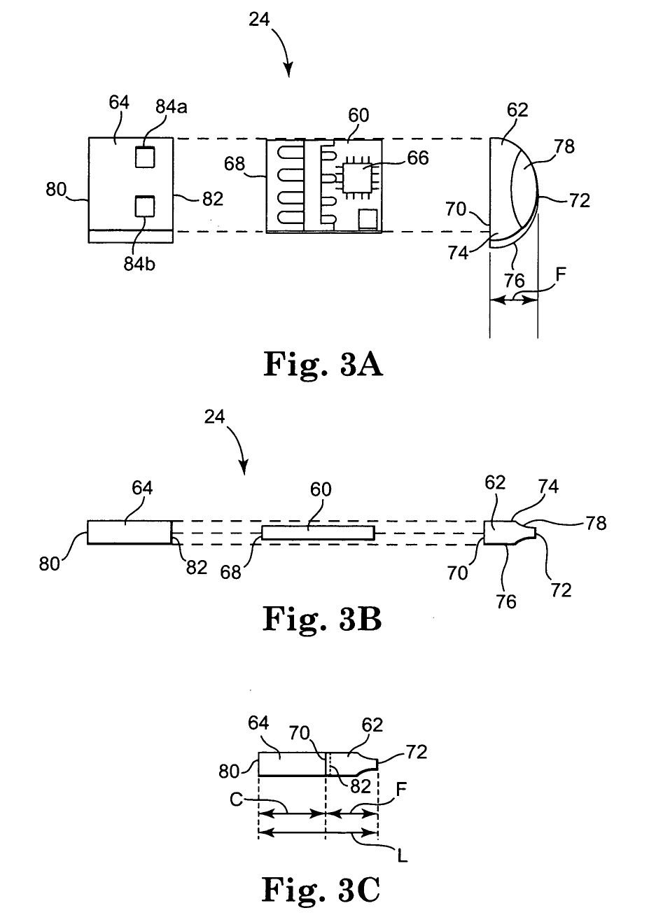

FIG. 3A illustrates an exploded, perspective view of an exemplary USB flash drive 24 according to one embodiment of the present invention. The USB flash drive 24 includes a printed circuit assembly 60, a case 62, and a connector 64, where the case 62 and the connector 64 combine to rigidly enclose the printed circuit assembly 60.

The printed circuit assembly 60 includes solid state integrated circuitry 66 and data access pads 68 that are electrically coupled to the integrated circuitry 66. In one embodiment, the integrated circuitry 66 includes multiple transistors having multiple transistor pairs separated by a thin layer of dielectric. For example, each transistor pair includes a floating gate separated from a control gate by a thin dielectric layer such that the transistor pair is configured for electron tunneling, which is useful in memory storage. In this regard, the circuitry 66 forms an electronically-erasable programmable read-only memory (EEPROM) that is consistent with the flash memory storage of data. Suitable circuit assemblies are available from Atmel Corporation, San Jose, Calif.

The case 62 defines a base end 70 and a trailing end 72 that is opposite the base end 70, and a top exterior surface 74 opposite a bottom exterior surface 76. In one embodiment, an extractor depression 78 formed in the top exterior surface 74. In this regard, the case 62 defines case length F that extends between the base end 70 and the trailing end 72. The case 62 protectively encloses at least a portion of the printed circuit assembly 60. In one embodiment, and with reference to FIG. 2, the case length F is minimized such that the case 62 minimally disrupts the footprint of the housing 28 beyond the end 52 from which it extends.

The connector 64 defines a leading end 80 and a trailing end 82 that is opposite the leading end 80. In one embodiment, the trailing end 82 is coupled to the base end 70 of the case 62, and the leading end 80 is sized and shaped to conform to USB standards. In this regard, the connector defines openings 84a, 84b configured to be received by retaining clips (not shown) inside a USB port (such as memory port 36 of FIG. 2). Thus, when the connector 64 is inserted, the openings 84a, 84b are engaged by the retaining clips and the leading end 80 “bottoms out” or “stops” inside the memory port 36 to limit the travel of the connector 64 into the USB port and ensure that the connector 64 is fully engaged within the USB port. In one embodiment, the case 62 is non-metallic and rigidly coupled to a metal connector 64, and the case 62 and the connector 64 combine to define a rigid enclosure housing the printed circuit assembly 60.

With reference to FIG. 2, when the computer 22 is operating, the CPU 35 accesses an operating system (OS) of the computer 22 and the integrated circuitry 66 of the printed circuit assembly 60 is employed to extend the OS memory. In particular, the USB flash drive 24 can provide random access memory (RAM) that is accessible by the CPU 35, which extends the OS memory of the computer system 20. This enables the system 20 to operate faster, especially when transferring data between programs in use. In this manner, the USB flash drive 24 extends the OS memory and increases performance of the computing system 20 without the need for a user to open the housing 28 and insert separate memory cards into the computer 22.

FIG. 3B illustrates an exploded side view and FIG. 3C illustrates an assembled side view of the USB flash drive 24 according to embodiments of the present invention. When assembled, the connector 64 is rigidly coupled to the case 62, and the case 62 and the connector 64 combine to enclose the printed circuit assembly 60. In particular, the trailing end 82 of the connector 64 is rigidly coupled to the base end 70 of the case 62, such that the connector 64 extends an exposed connector length C away from the base end 70 of the case 62. In one embodiment, the connector 64 is a USB connector that is insertable into a USB port such that substantially an entirety of the exposed connector length C is received within the USB port when the openings 84a, 84b (FIG. 3A) are engaged by the USB port.

In addition, the case 62 and the connector 64 combine to define an enclosure having a device length L extending between the leading end 80 of the connector 64 and the trailing end 72 of the case 62, and the case length F is less than 50% of the device length L. In this regard, the case length F of the case 62 is not greater than an exposed connector length C of the connector 64. In one embodiment, the case length F of the case 62 is less than the exposed connector length C of the connector 64. In another embodiment, the case length F of the case 62 is equal in length to the connector length C of the connector 64.

When assembled, the data access pads 68 of the printed circuit assembly 60 are accessible through an opening (not shown) formed in the leading end 80 of the connector 64. In this regard, and with additional reference to FIG. 2 above, the data access pads 68 are available to be electrically coupled to the memory port 36 when the connector 64 is inserted into the computer 22. The case length F is less than the connector length C, such that when the standard USB connector 64 is inserted into the memory port 36, the case length F extends from the housing 28 by less than 10 percent of the longitudinal dimension D and less than 10 percent of the lateral dimension W. It has been surprisingly discovered that a so-dimensioned case 62 minimally disrupts the footprint of the housing 28 and resists inadvertent removal of the flash drive 24 when the system 20 (FIGS. 1, 2) is ported and/or jostled.

As noted above, the case length F of the case 62 is minimized to minimally disrupt the footprint of the housing 28 (FIG. 2) from which it extends. Consequently, the manual removal of the USB flash drive 24 from the housing 28 can present a challenge. With this in mind, in one embodiment the case 62 includes a feature, such as the extractor depression 78, which assists in manual removal of the USB flash drive 24 from the housing 28. In one embodiment, the extractor depression 78 defines a concave surface that provides a gripping area that enables a user of the USB flash drive 24 to grasp the case 62 and remove/extract the USB flash drive from a computer port. To this end, in one embodiment the case 62 is formed from a soft, pliable polymer that is tacky (i.e., the exterior of the case 62 proximate the extractor depression 78 has a high coefficient of friction).

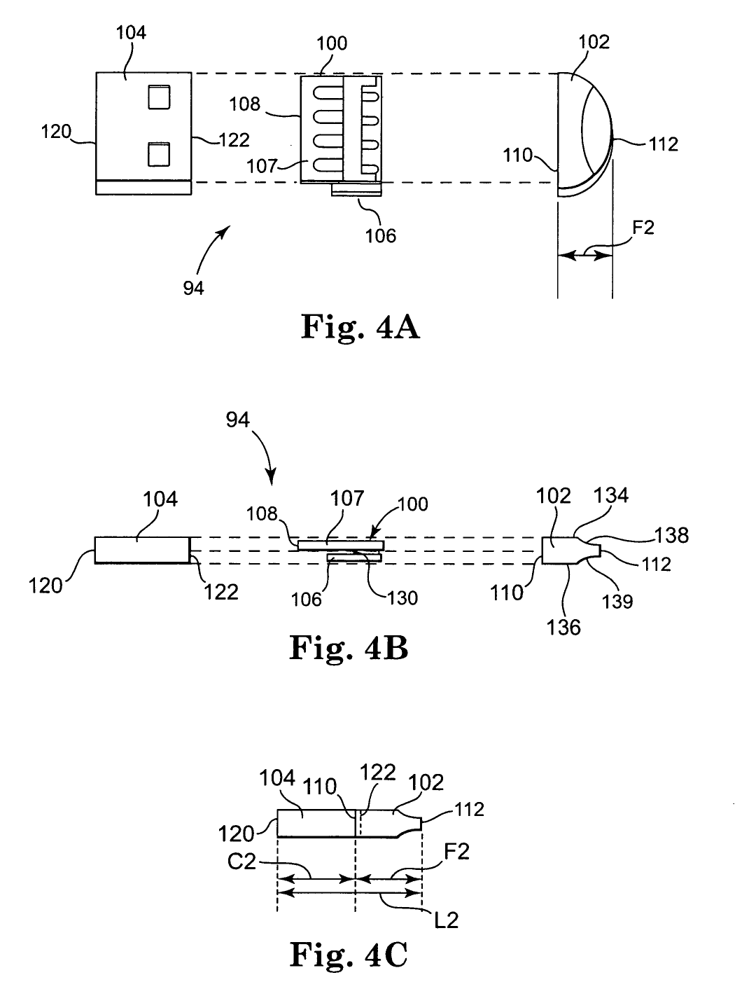

Suitable materials for forming the case 62 include thermoplastic polymers, in general, and rubbers including synthetic and natural rubbers. One suitable material for forming the case 62 includes Silastic™ LC-40-2004, a silicone rubber, available from Dow Corning STI, Inc., Kendallville, Ind. The softness or relative hardness of the material that forms the case 62 is quantified by a durometer value represented in Shore-A hardness. In one embodiment, the durometer of the material that forms the case 62 is between about 20-60 Shore-A, and preferably the durometer of the material that forms the case 62 has a durometer between about 35-45 Shore-A. Forming the case 62 from other polymers is also acceptable FIG. 4A illustrates an exploded, perspective view of another USB flash drive 94 memory storage device according to one embodiment of the present invention. The USB flash drive 94 includes a printed circuit assembly 100, a case 102, and a connector 104 rigidly coupled to the case 102. The case 102 and the connector 104 combine to rigidly enclose the printed circuit assembly 100.

In one embodiment, the printed circuit assembly 100 includes a first board 106 and a second board 107 that is electrically coupled to the first board 106. In one embodiment, one of the boards, for example, the first board 106, is a printed circuit board including integrated circuitry (not shown), and the other board, for example, the second board 107, is an interface board having data access pads 108 that electrically communicate with the integrated circuitry.

The case 102 defines a base end 110 and a trailing end 112 opposite the base end 110, and a case length F2 that extends between the base end 110 and the trailing end 112. In one embodiment, the trailing end 112 is arcuate, and curves between opposing sides of the case 102. In another embodiment, the trailing end 112 defines a portion of a circular arc, although curved shapes are also acceptable.

The connector 104 defines a leading end 120 and a trailing end 122 that is opposite the leading end 120. The case 102 and the connector 104 are similar to the case 62 and the connector 64 (FIG. 3A) described above. For example, in one embodiment the case 102 is non-metallic and the connector 104 is metal.

FIG. 4B illustrates an exploded side view and FIG. 4C illustrates an assembled side view of the USB flash drive 94 according to one embodiment of the present invention. The printed circuit assembly 100 includes multiple electrically coupled boards. For example, the printed circuit assembly 100 includes two boards, where the first board 106 is electrically connected to the second board 107 by an electrical connector 130. In this regard, the second board 107 is a “mezzanine” board relative to the first board 106.

In one embodiment, the boards 106, 107 are arranged, or stacked, to minimize their combined volume. For example, in one embodiment the first board 106 is stacked atop the second board 107, although other volume minimizing arrangements are also acceptable. In one embodiment, the electrical connector 130 is a rigid connector that physically separates the first board 106 a given distance from the second board 107. In general, one of the boards 106, 107 includes solid state circuitry that is electrically coupled to the data access pads 108.

In one embodiment, the case 102 defines a top exterior surface 134 and a bottom exterior surface 136, and each of the surfaces 134, 136 defines an extractor depression 138, 139, respectively. The case 102 is similar to the case 62 (FIGS. 3A and 3B) described above. In this regard, the case 102 is formed from soft polymers, such as Silastic™ LC-40-2004 silicone rubber, available from Dow Corning STI, Inc., Kendallville, Ind., having a durometer of between about 20-60 Shore-A, although other polymers are acceptable.

When assembled, the trailing end 122 of the connector 104 is rigidly coupled to the base end 110 of the case 102, and the connector 104 extends a connector length C2 from the base end 110 of the case 102. In addition, the case 102 and the connector 104 combine to define an enclosure having a device length L2 extending between the leading end 120 of the connector 104 and the trailing end 112 of the case 102, and the case length F2 is less than 50% of the device length L2.

The case 102 and the connector 104 combine to enclose the printed circuit assembly 100 such that the data access pads 108 are accessible through an opening (not shown) of the leading end 120 of the case 104. The extractor depressions 138, 139 are provided in the case 102 to enable a user to manually grasp and remove the USB flash drive 94 from an electronic device such as a computer.

Generally, the case length F2 is sized such that when the USB flash drive 94 is inserted into a computer system, for example, the computer system 20 (FIG. 2), the case length F2 extends from the housing 28 in a manner that minimally disrupts a footprint of the housing 28. In this regard, the case length F2 of the case 102 is not greater than an exposed connector length C2 of the connector 104. In one embodiment, the case length F2 is less than the exposed connector length C2 of the connector 104. In another embodiment, the case length F2 is equal in length to the exposed connector length C2 of the connector 104. To this end, the case length F2 extends from the footprint of the housing 28 by less than 10 percent of the longitudinal dimension D and less than 10 percent of the lateral dimension W.

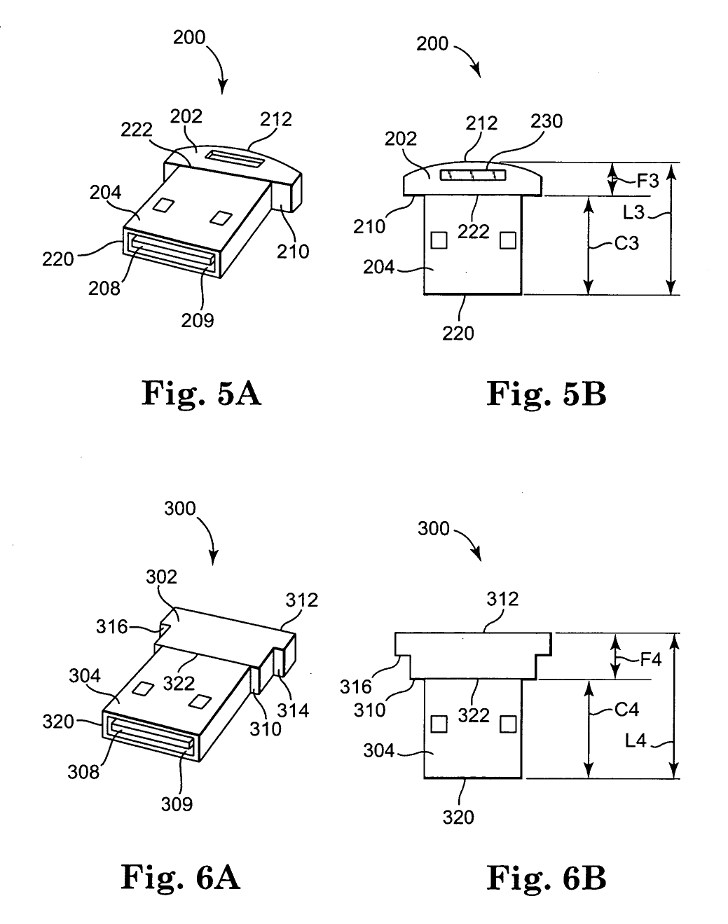

FIG. 5A illustrates a perspective view of another USB flash drive 200 according to one embodiment of the present invention. The USB flash drive 200 includes a case 202 and a connector 204 rigidly coupled to the case 202. The case 202 and the connector 204 combine to rigidly enclose a printed circuit assembly (not shown) having a board that includes data access pads 208 that are accessible through an opening 209 formed in the connector 204. In one embodiment, the connector 204 is a USB connector that conforms to the USB standards.

The case 202 defines a base end 210 and a trailing end 212 opposite the base end 210, and the connector 204 defines a leading end 220 and a trailing end 222 opposite the leading end 220. The trailing end 222 of the connector 204 is rigidly coupled to the base end 210 of the case 202. In one embodiment, the trailing end 212 of the case 202 is arcuate, as illustrated. In one embodiment, the trailing end 212 defines a portion of a circular arc, although other shapes for the trailing end 212 are also acceptable.

The case 202 is similar to the case 62 (FIGS. 3A and 3B) described above. In this regard, the case 202 is formed from soft polymers, such as Silastic™ LC-40-2004 silicone rubber, available from Dow Corning STI, Inc., Kendallville, Ind., having a durometer of between about 20-60 Shore-A, although other polymers are acceptable.

FIG. 5B illustrates a top view of the USB flash drive 200 according to one embodiment of the present invention. The case 202 defines a case length F3 that extends between the base end 210 and the trailing end 212, and the connector 204 defines an exposed connector length C3 that extends between the leading end 220 of the connector 204 and the base end 210 of the case 202. In one embodiment, the case length F3 of the case 202 is less than the connector length C3 of the connector 204. In another embodiment, the case length F3 of the case 202 is equal in length to the connector length C3 of the connector 204.

In addition, the case 202 and the connector 204 combine to define an enclosure having a device length L3 extending between the leading end 220 of the connector 204 and the trailing end 212 of the case 202, and the case length F3 is less than 50% of the device length L3.

Generally, the case length F3 is sized such that when the USB flash drive 200 is inserted into a computer system, for example, the computer system 20 (FIG. 2), the case length F3 of the case 202 extends from the housing 28 in a manner that minimally disrupts a footprint of the housing 28. For example, the case length F3 extends from the footprint of the housing 28 by less than 10 percent of the longitudinal dimension D and less than 10 percent of the lateral dimension W.

With this in mind, in one embodiment the case 202 includes an extraction feature that assists in the manual removal of the USB flash drive 200 from an electronic device into which it is inserted. For example, in one embodiment the case 202 defines an extractor slot 230 that is configured to receive a thumbnail, for example, of a user. Although only one extractor slot 230 is illustrated, it is to be understood that two, opposing extractor slots can be formed on opposing exterior surfaces of the case 202. By this means, the user can manually remove an inserted USB flash drive 200 even though the case length F3 of the case 202 minimally disrupts a footprint of the housing 28 (FIG. 2).

FIG. 6A illustrates a perspective view of another USB flash drive 300 according to one embodiment of the present invention. The USB flash drive 300 includes a case 302 and a connector 304 rigidly coupled to the case 302. The case 302 and the connector 304 combine to rigidly enclose a printed circuit assembly (not shown) having an interface board that includes data access pads 308 that are accessible through an opening 309 formed in the connector 304. In one embodiment, the connector 304 is a USB connector that conforms to the USB standards.

The case 302 defines a base end 310 and a trailing end 312 opposite the base end 310, and a pair of opposing ridges 314, 316 formed in opposing ends of the case 302. In one embodiment, the opposing ridges 314, 316 form extractor features that are useful in extracting the USB flash drive 300 from a memory port of a computer. The connector 304 defines a leading end 320 and a trailing end 322 opposite the leading end 320, and the trailing end 322 of the connector 304 is rigidly coupled to the base end 310 of the case 302.

The case 302 is similar to the case 62 (FIGS. 3A and 3B) described above. In this regard, the case 302 is formed from soft polymers, such as Silastic™ LC-40-2004 silicone rubber, available from Dow Coming STI, Inc., Kendallville, Ind., having a durometer of between about 20-60 Shore-A, although other polymers are acceptable.

FIG. 6B illustrates a top view of the USB flash drive 300 according to one embodiment of the present invention. The case 302 defines a case length F4 that extends between the base end 310 and the trailing end 312, and the connector 304 defines an exposed connector length C4 that extends between the leading end 320 of the connector 304 and the base end 310 of the case 302. In one embodiment, the case length F4 of the case 302 is less than the connector length C4 of the connector 304. In another embodiment, the case length F4 of the case 302 is equal in length to the connector length C4 of the connector 304.

In addition, the case 302 and the connector 304 combine to define an enclosure having a device length L4 extending between the leading end 320 of the connector 304 and the trailing end 312 of the case 302, and the case length F4 is less than 50% of the device length L4.

Generally, the case length F4 is sized such that when the USB flash drive 300 is inserted into a computer system, for example, the computer system 20 (FIG. 2), the case length F4 of the case 302 extends from the housing 28 in a manner that minimally disrupts a footprint of the housing 28. For example, the case length F4 is sized to extend from the footprint of the housing 28 by less than 10 percent of the longitudinal dimension D and less than 10 percent of the lateral dimension W.

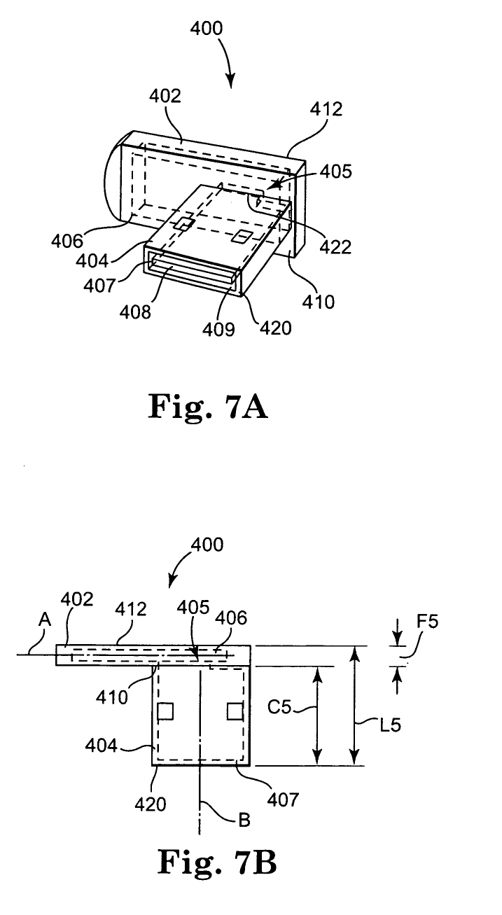

FIG. 7A illustrates a perspective view of another USB flash drive 400 according to one embodiment of the present invention. The USB flash drive 400 includes a case 402 and a connector 404 rigidly coupled to the case 402. The case 402 and the connector 404 combine to rigidly enclose a printed circuit assembly 405. The printed circuit assembly 405 includes a circuit board 406 and an interface board 407 electrically coupled to the circuit board 406. The interface board 407 includes data access pads 408 that are accessible through an opening 409 formed in the connector 404. In one embodiment, the connector 404 is a USB connector that conforms to the USB standards.

The case 402 defines a base end 410 and a trailing end 412 opposite the base end 410. In this regard, the base end 410 provides the connector 404 with access to at least a portion of the printed circuit assembly 405. The connector 404 defines a leading end 420 and a trailing end 422 opposite the leading end 420. The trailing end 422 of the connector 404 is rigidly coupled to the base end 410 of the case 402.

The case 402 is similar to the case 62 (FIGS. 3A and 3B) described above. In this regard, the case 402 is formed from soft polymers, such as Silastic™ LC-40-2004 silicone rubber, available from Dow Corning STI, Inc., Kendallville, Ind., having a durometer of between about 20-60 Shore-A, although other polymers are acceptable.

FIG. 7B illustrates a top view of the USB flash drive 400 according to one embodiment of the present invention. In one embodiment, the case 402 defines a major axis A along which the case 402 is aligned. In particular, the circuit board 406 is enclosed within the case 402 and aligned along the major axis A such that both the case 402 and the circuit board 406 extend minimally away from the trailing end 422 of the connector 404.

In one embodiment, the connector 404 defines a central axis B that bisects the leading end 420 and the trailing end 422. In one embodiment, the interface board 407 is enclosed within the connector 404 and electrically and mechanically coupled to the circuit board 406. In this regard, in one embodiment the major axis A of the case 402 is substantially orthogonal to the central axis B of the connector 404, such that the circuit board 406 is disposed substantially orthogonally to the interface board 407. In other words, the circuit board 406 is disposed transverse to the interface board 407.

The case 402 defines a case length F5 that extends between the base end 410 and the trailing end 412. When assembled, the connector 404 defines an exposed connector length C5 that extends between the leading end 420 of the connector 404 and the base end 410 of the case 402. In this regard, in one embodiment the case length F5 of the case 402 is less than the exposed connector length C5 of the connector 404. In another embodiment, the case length F5 is equal to the connector length C5.

In addition, the case 402 and the connector 404 combine to define an enclosure having a device length L5 extending between the leading end 420 of the connector 404 and the trailing end 412 of the case 402, and the case length F5 is less than 50% of the device length L5, and preferably the case length F5 is less than 30% of the device length L5.

Generally, the case length F5 is sized such that when the USB flash drive 400 is inserted into a computer system, for example, the computer system 20 (FIG. 2), the case length F5 of the case 402 minimally disrupts the footprint of the housing 28. For example, in one embodiment the case length F5 is sized to extend from the footprint of the housing 28 by less than 10 percent of the longitudinal dimension D and less than 10 percent of the lateral dimension W. In another embodiment, the case length F5 is sized to extend from the footprint of the housing 28 by less than 5 percent of the longitudinal dimension D and less than 5 percent of the lateral dimension W.

Various embodiments of USB flash drives have been described that improve the portability and usability of USB flash drives that are insertable in portable electronics. The USB flash drives can be used to extend OS memory of certain computer systems, and especially in systems that use large amounts of RAM. These USB flash drives can extend OS memory without the cumbersome and time consuming practice of opening the computer “box” to add memory cards. The USB flash drives minimally disrupt the footprint of the housing into which they are inserted. To this end, the USB flash drives of the present application are useful in ported and portable electronic devices.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A USB flash drive memory storage device comprising:
a printed circuit assembly;
a case defining a base end and a trailing end opposite the base end; and
a connector coupled to the case and extending a connector length from the base end of the case, the connector defining an opening through which data pads of the printed circuit assembly are accessible, the case and the connector combining to define an enclosure housing the printed circuit assembly;
wherein the case defines a case length extending between the base end and the trailing end that is not greater than the connector length.

2. The USB flash drive of claim 1, wherein the case and the connector are separately formed and combine to define a rigid enclosure housing the printed circuit assembly.

3. The USB flash drive of claim 1, wherein the printed circuit assembly includes a circuit board that is electrically coupled to an interface board, the printed circuit board being substantially enclosed within the case, and the interface board being substantially enclosed within the connector.

4. The USB flash drive of claim 1, wherein the case defines a major axis and the connector defines a leading end opposite a trailing end and a central axis bisecting the leading and trailing ends, the major axis substantially perpendicular to the central axis.

5. The USB flash drive of claim 4, wherein the case and the connector combine to define an enclosure having a device length extending between the leading end of the connector and the trailing end of the case, and further wherein the case length is less than 50% of the device length.

6. The USB flash drive of claim 1, wherein the trailing end of the case is arcuate.

7. The USB flash drive of claim 6, wherein the arcuate trailing end of the case defines a portion of a circular arc.

8. The USB flash drive of claim 1, wherein the trailing end of the case defines a top exterior surface opposite a bottom exterior surface, at least one of the top and bottom exterior surfaces defining an extractor depression.

9. The USB flash drive of claim 1, wherein the case comprises a polymer having a Shore-A durometer of between about 20-60.

10. The USB flash drive of claim 9, wherein the polymer is a silicone rubber.

11. The USB flash drive of claim 1, wherein the case length is equal to the connector length.

12. The USB flash drive of claim 1, wherein the case length is less than the connector length.

13. A computing system comprising:
a housing defining an enclosure and a memory port, the housing including a footprint having a longitudinal dimension extending between opposing sides of the housing and a lateral dimension extending between opposing ends of the housing;
a central processing unit disposed within the enclosure; and
a USB flash drive including:
a printed circuit assembly,
a case defining a case length extending between a base end and a trailing end opposite the base end,
a connector coupled to the case and removably coupleable to the memory port, the case and the connector combining to define a rigid enclosure housing the printed circuit assembly;
wherein when the USB flash drive is inserted into the memory port, the case length extends from the footprint of the housing by less than 10% of the longitudinal dimension and less than 10% of the lateral dimension.

14. The computing system of claim 13, wherein the connector extends a connector length from the base end of the case, and further wherein the case length is not greater than the connector length.

15. The computing system of claim 13, wherein the printed circuit assembly includes a circuit board that is electrically coupled to an interface board, the printed circuit board being substantially enclosed within the case, and the interface board being substantially enclosed within the connector.

16. The computing system of claim 15, wherein the case defines a major axis and the connector defines a leading end opposite a trailing end and a central axis bisecting the leading and trailing ends, the circuit board enclosed within the case and aligned along the major axis and the interface board enclosed within the connector and aligned along the central axis.

17. The computing system of claim 16, wherein the major axis is substantially perpendicular to the central axis.

18. A method of accessing system memory of a portable electronic device, the method comprising:
providing a portable computer having a system memory;
providing an external memory device including:
a printed circuit assembly,
a case defining a case length extending between a base end and a trailing end opposite the base end,
a connector coupled to and extending a connector length from the base end of the case, the case and the connector combining to rigidly enclose the printed circuit assembly; and
plugging a leading end of the connector of the external memory device into a USB port of the computer, the external memory device providing an accessible extension of the system memory;
wherein the case and the connector combine to define an enclosure having a device length extending between the leading end of the connector and the trailing end of the case, and further wherein the case length is less than 50% of the device length.

19. The method of claim 18, wherein the case defines a major axis and the connector defines a trailing end opposite the leading end and a central axis bisecting the leading and trailing ends, the major axis substantially perpendicular to the central axis.

20. The method of claim 18, wherein the case defines a case length extending between the base end and the trailing end that is not greater than the connector length.
